(19) United States
(12) Patent Application Publication
(10) Pub. No.: US 2023/0377882 A1
(43) Pub. Date: Nov. 23, 2023

(54) LOW DEFECT SEMICONDUCTOR FORMATION TECHNIQUES

(71) Applicant: Analog Devices, Inc., Wilmington, MA (US)

(72) Inventors: James G. Fiorenza, Carlisle, MA (US); Daniel Piedra, Somerville, MA (US)

(21) Appl. No.: 18/196,733

(22) Filed: May 12, 2023

Related U.S. Application Data
(60) Provisional application No. 63/342,771, filed on May 17, 2022.

(51) Int. Cl. H01L 21/02; H01L 29/20; H01L 29/778; H01L 29/66

(52) U.S. Cl. CPC H01L 21/02694; H01L 29/2003; H01L 29/7786; H01L 29/66462; H01L 21/02378; H01L 21/02458; H01L 21/0254

(57) ABSTRACT

During gallium nitride (GaN) semiconductor fabrication, a nucleation layer, e.g., aluminum nitride (AlN) may be formed superjacent a substrate, e.g., silicon carbide (SiC). Next, a semiconductor layer, such as including GaN, may be formed over the nucleation layer. This disclosure describes various techniques for forming a thick enough layer of gallium nitride (GaN) to ensure complete coalescence and minimal surface roughness, then removing the excess GaN until a desired thickness is achieved. In some examples, the GaN removal may be performed by desorption, such as may be performed in-situ by using hydrogen gas close to the growth temperature.

### CLAIM OF PRIORITY

This application claims the benefit of priority of U.S. Provisional Patent Application Ser. No. 63/342,771, titled “LOW DEFECT SEMICONDUCTOR FORMATION TECHNIQUES” to James G. Fiorenza et al., filed on May 17, 2022, the entire contents of which being incorporated herein by reference.

### STATEMENT REGARDING FEDERALLY SPONSORED RESEARCH OR DEVELOPMENT

This invention was made with government support under Grant No. HR0011-18-3-0014 awarded by the Defense Advanced Research Projects Agency (DARPA). The government has certain rights in the invention.

### FIELD OF THE DISCLOSURE

This document pertains generally, but not by way of limitation, to semiconductor devices, and more particularly, to techniques for constructing gallium nitride devices.

### BACKGROUND

Gallium nitride based semiconductors offer several advantages over other semiconductors as the material of choice for fabricating the next generation of transistors, or semiconductor devices, for use in both high-voltage and high-frequency applications. Gallium nitride (GaN) based semiconductors, for example, have a wide-bandgap that enable devices fabricated from these materials to have a high breakdown electric field and to be robust to a wide range of temperatures. The two-dimensional electron gas (2DEG) channels formed by GaN based heterostructures generally have high electron mobility, making devices fabricated using these structures useful in power-switching and amplification systems.

### SUMMARY OF THE DISCLOSURE

During gallium nitride (GaN) semiconductor fabrication, a nucleation layer, e.g., aluminum nitride (AlN) may be formed superjacent a substrate, e.g., silicon carbide (SiC). Next, a semiconductor layer, such as including GaN, may be formed over the nucleation layer. This disclosure describes various techniques for forming a thick enough layer of gallium nitride (GaN) to ensure complete coalescence and minimal surface roughness, then removing the excess GaN until a desired thickness is achieved. In some examples, the GaN removal may be performed by desorption, such as may be performed in-situ by using hydrogen gas close to the growth temperature.

In some aspects, this disclosure is directed to a method of fabricating a semiconductor wafer to reduce or counteract defects, the method comprising forming a substrate layer; forming a nucleation layer superjacent the substrate layer; forming a semiconductor layer, superjacent the nucleation layer, to at least a first thickness; and reducing a thickness of the semiconductor layer to at least a second thickness.

In some aspects, this disclosure is directed to a semiconductor device comprising: a nucleation layer formed superjacent a substrate layer; a first semiconductor layer formed superjacent the nucleation layer to at least a first thickness and then reduced to at least a second thickness by performing a hydrogen bake treatment to desorb the semiconductor layer; a second semiconductor layer formed superjacent the first semiconductor layer to form a heterostructure configured to form a two-dimensional electron gas (2DEG) channel; and a gate electrode formed superjacent the second semiconductor layer; and a drain electrode and a source electrode.

In some aspects, this disclosure is directed to a method of fabricating a semiconductor wafer to reduce or counteract defects, the method comprising: forming a substrate layer; forming a nucleation layer superjacent the substrate layer; forming a first semiconductor layer, superjacent the nucleation layer, to at least a first thickness; reducing a thickness of the first semiconductor layer to at least a second thickness by performing a hydrogen bake treatment to desorb the first semiconductor layer; and forming a second semiconductor layer superjacent the first semiconductor layer including forming a heterostructure configured to form a two-dimensional electron gas (2DEG) channel.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 depicts an example of a semiconductor wafer.

FIG. 2 depicts a scanning electron microscope (SEM) image of a portion of the wafer of FIG. 1.

FIG. 3 depicts a transmission electron microscopy (TEM) image of a cross-section of the portion of the wafer shown in FIG. 2.

FIG. 4 depicts a transmission electron microscopy (TEM) image of a cross-section of the region shown in FIG. 3.

FIGS. 5A-5D depict an example of a process flow for fabricating a semiconductor wafer to reduce or counteract defects.

### DETAILED DESCRIPTION

Gallium nitride (GaN) semiconductors offer several advantages over other semiconductors as the material of choice for fabricating the next generation of transistors, or semiconductor devices, for use in both high-voltage and high-frequency applications. During semiconductor fabrication, a nucleation layer, e.g., aluminum nitride (AlN) may be formed superjacent a substrate, e.g., silicon carbide (SiC). The nucleation layer is an epitaxial layer grown on the substrate to facilitate the growth of another layer, e.g., a GaN layer, which would otherwise be difficult or impossible due to lattice mismatch or thermal expansion mismatch between the desired layer and the substrate.

Next, a semiconductor layer, such as including GaN, may be formed over the nucleation layer.

The present inventors have recognized that a thin GaN layer, such as about 50 nanometers (nm) to about 100 nm, may be desirable for at least two reasons. First, a thin GaN layer may be less expensive to produce because less time in a reactor is needed, which means less energy and gas required to fabricate the device. Second, some transistor structures operate most effectively when the distance between the transistor electrodes and the backside field plate is reduced.

The present inventors have recognized that if the GaN layer is too thin, however, there may be epitaxial uniformity issues or defects. For example, the present inventors have recognized that instead of forming a uniform film, islands of film may be formed that are not completely coalesced with one another. As a result, the GaN film is not uniform or planar and instead has isolated regions having varying degrees of thickness. However, if the GaN film has sufficient thickness, the islands of film merge and coalesce such that the GaN film is desirably uniform and planar.

This disclosure describes various techniques for forming a thick enough layer of GaN to ensure complete coalescence and minimal surface roughness, then removing the excess GaN until a desired thickness is achieved. In some examples, the GaN removal may be performed by desorption, such as may be performed in-situ by using hydrogen gas close to the growth temperature.

As used in this disclosure, a GaN-based compound semiconductor material can include a chemical compound of elements including GaN and one or more elements from different groups in the periodic table. Such chemical compounds can include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table can also be referred to as Group III and group 15 as Group V. In an example, a semiconductor device can be fabricated from GaN and aluminum indium gallium nitride (AlInGaN).

Heterostructures described herein can be formed as AlN/GaN/AlN hetero-structures, InAlN/GaN heterostructures, AlGaN/GaN heterostructures, or heterostructures formed from other combinations of group 13 and group 15 elements. These heterostructures can form a two-dimensional electron gas (2DEG) at the interface of the compound semiconductors that form the heterostructure, such as the interface of GaN and AlGaN. The 2DEG can form a conductive channel of electrons that can be controllably depleted, such as by an electric field formed by a buried layer of p-type material disposed below the channel. The conductive channel of electrons that can also be controllably enhanced, such as by an electric field formed by a gate terminal disposed above the channel to control a current through the semiconductor device. Semiconductor devices formed using such conductive channels can include high electron mobility transistors.

FIG. 1 depicts an example of a semiconductor wafer 100. The wafer 100 may be positioned within a reactor using a holder 102. As seen in FIG. 1, there is a hazy area 104 around the edge of the wafer. In the example shown, the hazy area 104 may form a border of about 1.5 centimeters (cm) around the edge of the wafer 100. The hazy area 104 may be the result of the epitaxial uniformity issues or defects mentioned above.

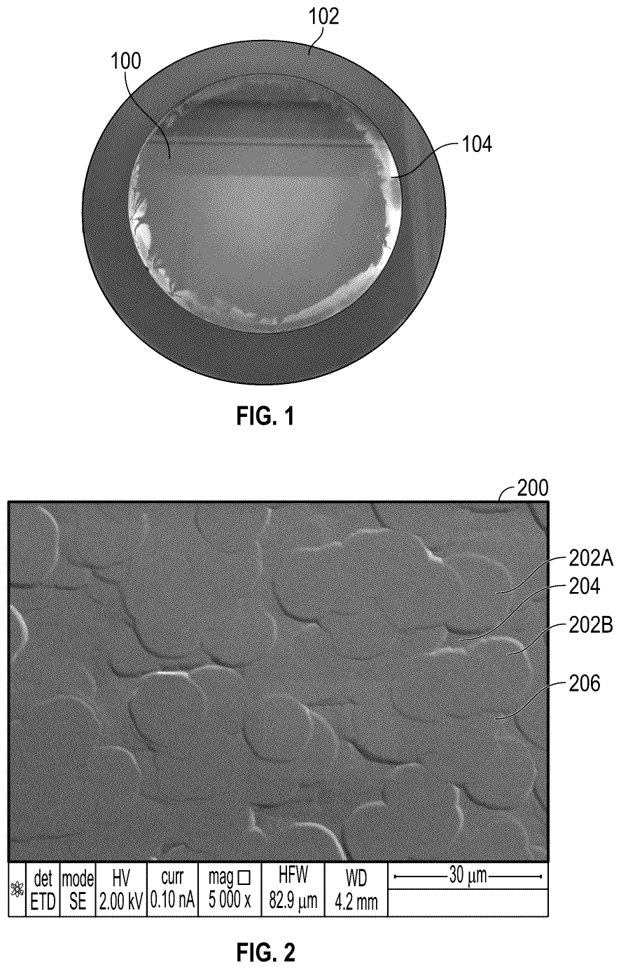

FIG. 2 depicts a scanning electron microscope (SEM) image 200 of a portion of the wafer 100 of FIG. 1. The image 200 has a scale of 30 micrometers. The image 200 illustrates a portion of the top of the hazy area 104 of FIG. 1.

Instead of a uniform, flat surface, the image 200 depicts islands of film, such as gallium nitride (GaN) that are not completely coalesced with one another, resulting in a top epilayer surface that is particularly rough. For example, the image 200 depicts a first island of film 202A separated from a second island of film 202B by a region 204.

These islands of film 202A, 202B are defects that may impact the mobility and the electron concentration of the AlGaN/GaN 2DEG, for example. The roughness may be measured with an atomic force microscope (AFM). If the film 206 had sufficient thickness, the islands of film would merge and coalesce and the islands would not be present.

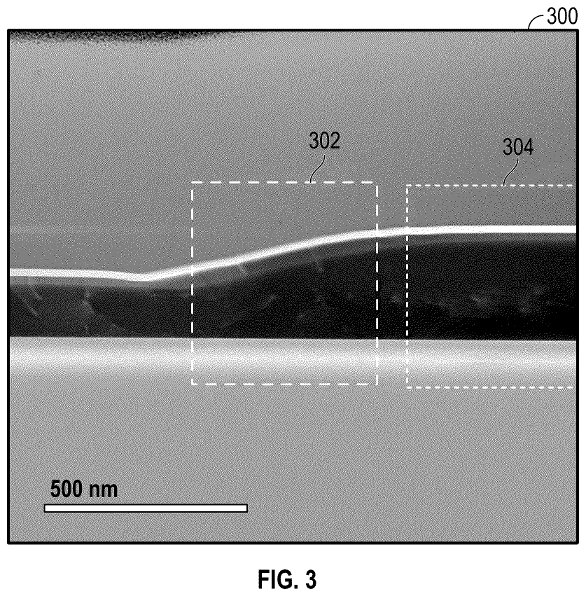

FIG. 3 depicts a transmission electron microscopy (TEM) image 300 of a cross-section of the portion of the wafer 100 shown in FIG. 2. The image 300 has a scale of 500 nanometers. The image 300 illustrates the varying thickness of the film in FIG. 2. For example, region 302 illustrates a varying thickness, in contrast with region 304, which depicts a substantial constant thickness.

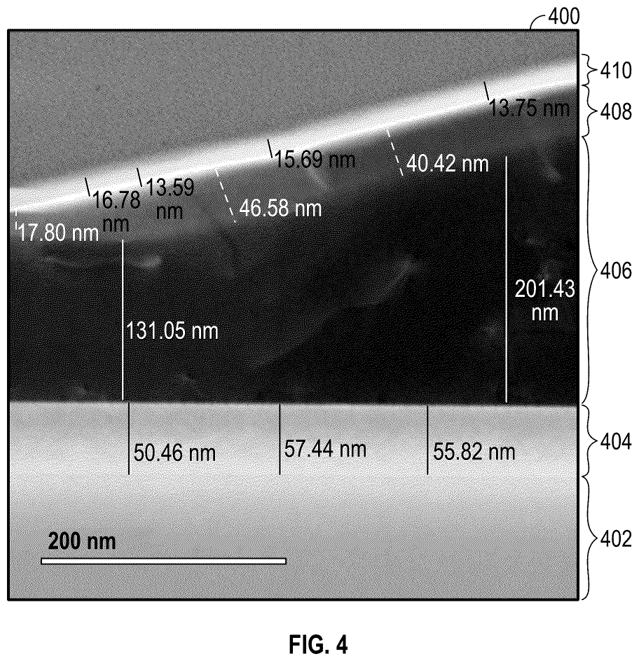

FIG. 4 depicts a transmission electron microscopy (TEM) image 400 of a cross-section of the region 302 shown in FIG. 3. The image 400 has a scale of 200 nanometers. The portion of the wafer shown in FIG. 4 includes a substrate layer 402 (e.g., silicon carbide), a nucleation layer 404 (e.g., aluminum nitride), a first semiconductor layer 406 (e.g., GaN), a second semiconductor layer 408 (aluminum gallium nitride (AlGaN)), and an insulator layer 410 (e.g., silicon nitride (SiN)).

Although the substrate layer 402 and the nucleation layer 404 are planar, the first semiconductor layer 406 is not planar. As seen in FIG. 4, the first semiconductor layer 406 varies in thickness. In some areas, the thickness of the first semiconductor layer 406 is 131.05 nanometers (nm) and in other areas the thickness is 201.43 nm.

The present inventors have recognized that if the first semiconductor layer 406 is too thin, however, there may be epitaxial uniformity issues or defects. For example, the present inventors have recognized that instead of forming a uniform film, islands of film may be formed that are not completely coalesced with one another. As a result, the film, e.g., GaN film, is not uniform or planar and instead has isolated regions having varying degrees of thickness. However, if the GaN film has sufficient thickness, the islands of film merge and coalesce such that the GaN film is desirably uniform and planar.

As shown in FIG. 4, a process may form a sufficiently thick layer of a semiconductor material, e.g., GaN, to ensure complete coalescence and minimal surface roughness. Then, an excess of the semiconductor material may be removed until a desired thickness is achieved.

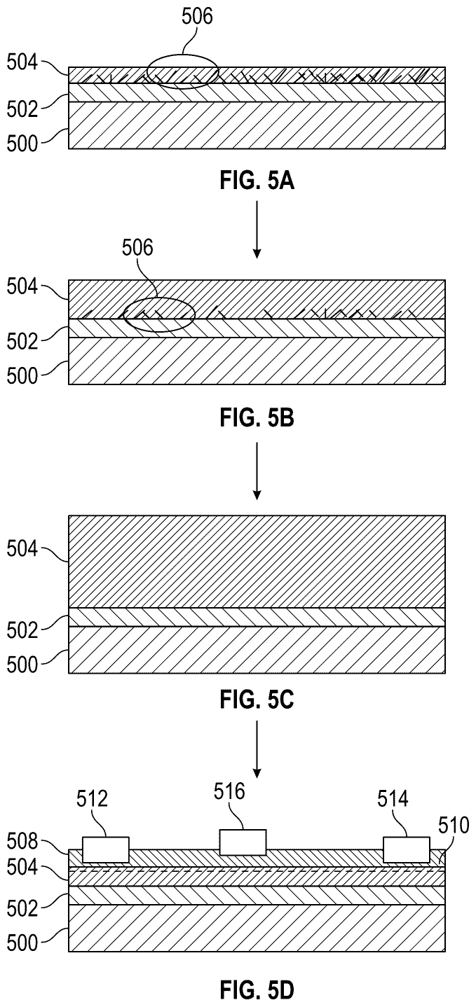

FIGS. 5A-5D depict an example of a process flow for fabricating a semiconductor wafer to reduce or counteract defects. In FIG. 5A, a substrate layer 500 is shown, such as silicon carbide. In some examples, the silicon carbide may be highly resistive silicon carbide, such as high purity silicon carbide that does not include vanadium doping. In some examples, the silicon carbide may be doped with vanadium.

A nucleation layer 502 may be formed superjacent the substrate layer 500. The nucleation layer 502 may include aluminum nitride or aluminum gallium nitride, for example.

A first semiconductor layer 504, e.g., gallium nitride, may be formed, e.g., grown, superjacent the nucleation layer 502. Some of the defects in the first semiconductor layer 504 are highlight as defects 506. The defects 506 may be similar to those shown in FIG. 2.

In FIG. 5B, the first semiconductor layer 504 layer continues formation and increases in thickness. In the representation shown in FIG. 5B, the defects 506 are decreasing as the first semiconductor layer 504 continues to coalesce.

In FIG. 5C, the first semiconductor layer 504 layer continues formation and increases in thickness to at least a first thickness. For example, the semiconductor layer may be formed, superjacent the nucleation layer, to at least a thickness of 250 nanometers. In the representation shown in FIG. 5C, the defects 506 of FIGS. 5A and 5B are no longer present as the first semiconductor layer 504 has completely coalesced.

In FIG. 5D, a thickness of the first semiconductor layer 504 may be reduced to at least a second thickness that is different than the first thickness of FIG. 5C. As a non-limiting example, the second thickness of the first semiconductor layer 504 may be reduced to at least a thickness of 100 nanometers. As another non-limiting example, if the first semiconductor layer 504 in FIG. 5C were formed to a first thickness of 2 microns (2000 nanometers), for example, the first semiconductor layer 504 may be reduced to a second thickness substantially thicker than 100 nanometers, such as to at least a thickness of 1 micron (1000 nanometers).

In some examples, reducing a thickness of the first semiconductor layer 504 to at least a second thickness may include etching away the thickness of the first semiconductor layer 504. In some examples, etching away the thickness of the first semiconductor layer 504 may include performing a hydrogen bake treatment to desorb the first semiconductor layer 504. In a non-limiting example, a hydrogen bake treatment may desorb about 750 nm GaN in about 5 minutes. An example of a temperature range is about 800° C. to about 1100° C. and an example of a range of pressures is about 100 millibars (mbar) to about 500 mbar.

In some examples, such as shown in FIG. 5D, a second semiconductor layer 508, e.g., aluminum gallium nitride, may be formed superjacent the first semiconductor layer. The second semiconductor layer 508 formed superjacent the first semiconductor layer 504 may form a compound semiconductor heterostructure having a two-dimensional electron gas (2DEG) channel 510 (represented by a dashed line), where the 2DEG channel is more conductive than either the first semiconductor layer 504 or the second semiconductor layer 508.

In some examples, such as shown in FIG. 5D, one or more electrodes may be formed superjacent the second semiconductor layer 508. For example, a first electrode 512 and a second electrode 514 may be formed. In an example, the first electrode 512 may be an anode and the second electrode may be a cathode.

In some examples, a third electrode 516 may be formed. In an example, the first electrode 512 may be a source electrode, the second electrode 514 may be a drain electrode, and the third electrode 516 may be a gate electrode of a field-effect transistor, such as a GaN high electron mobility transistor (HEMT).

### Various Notes

Each of the non-limiting aspects or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in a aspect are still deemed to fall within the scope of that aspect. Moreover, in the following aspects, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the aspects. Also, in the above Detailed Description, various features may be grouped together to streamline the disclosure. This should not be interpreted as intending that an unclaimed disclosed feature is essential to any aspect. Rather, inventive subject matter may lie in less than all features of a particular disclosed embodiment. Thus, the following aspects are hereby incorporated into the Detailed Description as examples or embodiments, with each aspect standing on its own as a separate embodiment, and it is contemplated that such embodiments may be combined with each other in various combinations or permutations. The scope of the invention should be determined with reference to the appended aspects, along with the full scope of equivalents to which such aspects are entitled.

1. A method of fabricating a semiconductor wafer to reduce or counteract defects, the method comprising:
forming a substrate layer;
forming a nucleation layer superjacent the substrate layer;
forming a semiconductor layer, superjacent the nucleation layer, to at least a first thickness; and
reducing a thickness of the semiconductor layer to at least a second thickness.

2. The method of claim 1, wherein reducing the thickness of the semiconductor layer to at least the second thickness includes:
etching away the thickness of the semiconductor layer.

3. The method of claim 2, wherein etching away the thickness of the semiconductor layer includes:
performing a hydrogen bake treatment to desorb the semiconductor layer.

4. The method of claim 1, wherein the semiconductor layer is a first semiconductor layer, the method comprising:
forming a second semiconductor layer superjacent the first semiconductor layer.

5. The method of claim 4, wherein forming the second semiconductor layer superjacent the first semiconductor layer includes:
forming a heterostructure configured to form a two-dimensional electron gas (2DEG) channel.

6. The method of claim 4, wherein forming the second semiconductor layer superjacent the first semiconductor layer includes:
forming a gallium nitride layer superjacent an aluminum gallium nitride layer.

7. The method of claim 4, comprising:
forming an electrode superjacent the second semiconductor layer.

8. The method of claim 7, wherein the electrode is a gate electrode, the method further comprising:
forming a drain electrode and a source electrode.

9. The method of claim 1, wherein forming a substrate layer includes:
forming a silicon carbide layer.

10. The method of claim 9, wherein forming a silicon carbide layer includes:
forming a high purity silicon carbide layer.

11. The method of claim 9, wherein forming a silicon carbide layer includes:
forming a vanadium-doped silicon carbide layer.

12. The method of claim 1, wherein forming the semiconductor layer, superjacent the nucleation layer, to at least the first thickness includes:
forming the semiconductor layer, superjacent the nucleation layer, to at least a thickness of 250 nanometers.

13. The method of claim 1, wherein reducing the thickness of the semiconductor layer to at least the second thickness includes:
reducing the thickness of the semiconductor layer to at least a thickness of 100 nanometers.

14. The method of claim 1, wherein reducing the thickness of the semiconductor layer to at least a second thickness includes:
reducing the thickness of the semiconductor layer to at least a thickness of 1000 nanometers.

15. A semiconductor device comprising:
a nucleation layer formed superjacent a substrate layer;
a first semiconductor layer formed superjacent the nucleation layer to at least a first thickness and then reduced to at least a second thickness by performing a hydrogen bake treatment to desorb the semiconductor layer;
a second semiconductor layer formed superjacent the first semiconductor layer to form a heterostructure configured to form a two-dimensional electron gas (2DEG) channel;
a gate electrode formed superjacent the second semiconductor layer; and
a drain electrode and a source electrode.

16. The semiconductor device of claim 15, wherein the substrate layer includes a silicon carbide.

17. A method of fabricating a semiconductor wafer to reduce or counteract defects, the method comprising:
forming a substrate layer;
forming a nucleation layer superjacent the substrate layer;
forming a first semiconductor layer, superjacent the nucleation layer, to at least a first thickness;
reducing a thickness of the first semiconductor layer to at least a second thickness by performing a hydrogen bake treatment to desorb the first semiconductor layer; and
forming a second semiconductor layer superjacent the first semiconductor layer including forming a heterostructure configured to form a two-dimensional electron gas (2DEG) channel.

18. The method of claim 17, wherein forming the second semiconductor layer superjacent the first semiconductor layer includes:
forming a gallium nitride layer superjacent an aluminum gallium nitride layer.

19. The method of claim 17, wherein forming the first semiconductor layer, superjacent the nucleation layer, to at least the first thickness includes:
forming the first semiconductor layer, superjacent the nucleation layer, to at least a thickness of 250 nanometers.

20. The method of claim 17, wherein reducing the thickness of the first semiconductor layer to at least the second thickness includes:
reducing the thickness of the semiconductor layer to at least a thickness of 100 nanometers.
